(19) United States
(12) Patent Application Publication
(10) Pub. No.: US 2025/0372945 A1
(43) Pub. Date: Dec. 4, 2025

(54) IMAGE FORMING APPARATUS

(71) Applicant: BROTHER KOGYO KABUSHIKI KAISHA, Nagoya (JP)

(72) Inventor: Shunsuke AIBA, Nagoya (JP)

(73) Assignee: BROTHER KOGYO KABUSHIKI KAISHA, Nagoya (JP)

(21) Appl. No.: 19/182,958

(22) Filed: Apr. 18, 2025

(30) Foreign Application Priority Data
May 31, 2024 (JP) 2024-088816

(51) Int. Cl. H01S 5/042; B41J 2/455; B41J 2/47; G02B 26/12; G03G 15/00; G03G 15/01; G03G 15/04; G03G 15/041

(52) U.S. Cl. CPC H01S 5/0428; B41J 2/455; B41J 2/473; G02B 26/12; G03G 15/011; G03G 15/0194; G03G 15/04036; G03G 15/0415; G03G 15/5004; G03G 15/80

(57) ABSTRACT

An image forming apparatus includes a laser unit including a semiconductor laser, a polygon mirror, an LD driver, and an LD board including an LD reference potential section. The image forming apparatus includes a photoconductor drum, a controller configured to output a pulse-width modulation signal to indicate a reference potential, and a main board including a main reference potential section configured to provide the reference voltage of the controller, the main reference potential section being electrically connected to the LD reference potential section via a harness. The LD board includes a voltage generation circuit configured to generate a particular voltage, a switching circuit configured to output an ON-voltage and an OFF-voltage alternately based on the pulse-width modulation signal, and a smoothing circuit configured to generate the reference voltage by smoothing the ON-voltage and the OFF-voltage output by the switching circuit.

### REFERENCE TO RELATED APPLICATIONS

This application claims priority from Japanese Patent Application No. 2024-088816 filed on May 31, 2024. The entire content of the priority application is incorporated herein by reference.

### BACKGROUND ART

The present disclosure relates to an image forming apparatus having a laser unit including an LD driver to control a light emission amount of a semiconductor laser based on a reference voltage.

Conventionally, it is known an image forming apparatus that is configured to adjust a light emission amount of a semiconductor laser based on a reference voltage, in order to expose a photoconductor drum using the semiconductor laser. In one known image forming device, an engine controller outputs a PWM (Pulse Width Modulation) signal to a drive circuit, and the drive circuit generates a reference voltage by smoothing the voltage that is switched on and off by the PWM signal, and adjusts the light emission amount from a laser diode (i.e., a semiconductor laser) based on that reference voltage.

### SUMMARY

An image forming apparatus is typically provided with a laser unit including a semiconductor laser and an LD driver configured to control the light emission amount of the semiconductor laser based on a reference voltage, and a controller configured to output a voltage to an LD board based on a PWM signal. There is known an image forming apparatus configured such that the LD board, on which the LD driver is mounted, and a main board, on which the controller is mounted, are connected via a harness.

When the harness between the main board and the LD board becomes longer, the resistance of the harness and the current flowing through it cause a voltage difference in the reference potentials (GND) between the main board and the LD board. Although the controller adjusts the value of the reference voltage based on a duty cycle of the PWM signal, the voltage difference may cause a deviation between the intended reference voltage set by the controller and the actual reference voltage input to the LD driver. This deviation may prevent the LD driver from properly adjusting the light emission amount of the semiconductor laser.

According to aspects of the present disclosure, an image forming apparatus includes a laser unit including a semiconductor laser, a polygon mirror configured to deflect a laser beam emitted from the semiconductor laser, an LD driver configured to control light emission amount of the semiconductor laser based on a reference voltage, and an LD board including an LD reference potential section configured to provide a reference potential for the LD driver, the LD driver being mounted on the LD board, a photoconductor drum configured to be exposed to the laser beam deflected by the polygon mirror, a controller including hardware and configured to output a pulse-width modulation signal to indicate the reference potential to the LD driver, and a main board implemented with the controller, the main board including a main reference potential section configured to provide a reference potential of the controller, the main reference potential section being electrically connected to the LD reference potential section via a harness. The LD board includes a voltage generation circuit configured to generate a particular voltage with reference to the reference potential of the LD driver, a switching circuit configured to output an ON-voltage and an OFF-voltage alternately based on the pulse-width modulation signal, the ON-voltage being based on the particular voltage, the OFF-voltage being the reference potential of the LD driver, and a smoothing circuit configured to generate the reference voltage by smoothing the ON-voltage and the OFF-voltage output by the switching circuit and to output the generated reference voltage to the LD driver.

### BRIEF DESCRIPTION OF DRAWINGS

FIG. 1 is a cross-sectional view showing a schematic configuration of a color laser printer.

FIG. 2 is a block diagram illustrating an electrical connection relationship between a main board and a laser unit.

FIG. 3 is a top view of the laser unit, illustrating a path of a beam emitted from a semiconductor laser to a BD sensor.

FIG. 4 is a plan view of an LD board showing a surface on which an LD driver is mounted.

FIG. 5 is a circuit diagram of the LD board.

FIGS. 6A and 6B show a diagram explaining an input voltage that is output by a switching circuit to a first smoothing circuit.

FIGS. 7A and 7B show circuit diagrams explaining an input voltage supplied to the first smoothing circuit in a comparative example.

FIG. 8A illustrates an input voltage supplied to the first smoothing circuit and a reference voltage output by the first smoothing circuit.

FIG. 8B illustrates an input voltage supplied to the first smoothing circuit and the reference voltage output by the first smoothing circuit in a comparative example.

FIGS. 9A and 9B show circuit diagrams illustrating voltage generation circuits.

### DESCRIPTION

### First Embodiment

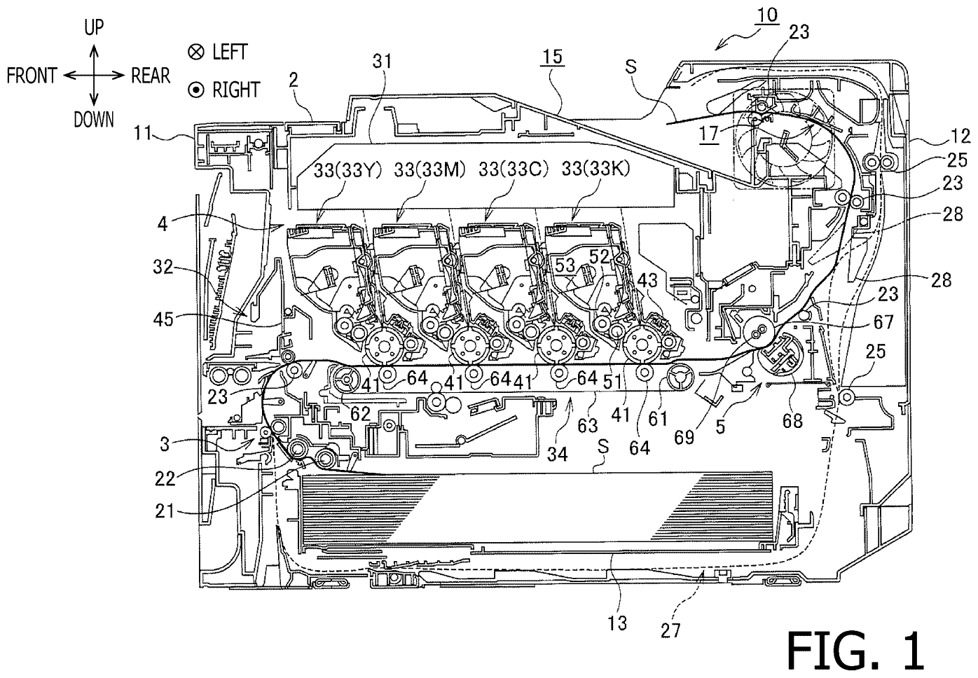

Hereinafter, a color laser printer 10 according to the present disclosure will be described with reference to drawings. FIG. 1 is a cross-sectional view illustrating a schematic configuration of the color laser printer 10 according to a first embodiment. The color laser printer 10 is an example of an image forming apparatus according to the present disclosure. Hereinafter, the color laser printer 10 will be referred to simply as the “printer” 10. The printer 10 includes a main housing 2, a conveyance mechanism 3, a process engine 4, and a fixing device 5. For clarity, the vertical and front-back directions of the printer 10 are defined as indicated by arrows in FIG. 1. Additionally, the near side (the side closer to the reader/viewer) with respect to a plane of FIG. 1 is defined as the right, and the far side with respect to the plane of FIG. 1 is defined as the left of the printer 10.

The main housing 2 includes an openable and closable front cover 11 and a rear cover 12, a supply tray 13, and a discharge tray 15, and has a conveyance path 17 defined therein. The supply tray 13 is detachably mounted at a lower part of the main housing 2. Sheets S are placed on the supply tray 13. The sheets S are standard-sized paper, such as A4. Note that the sheets S are not limited to paper media such as plain paper or thick paper but may also include other recording media, such as transparency films (e.g., OHP films). The discharge tray 15 is provided at an upper part of the main housing 2, and the sheets S with images formed thereon are placed on the discharge tray 15.

The conveyance mechanism 3 includes a pickup roller 21, a separation roller 22, and a plurality of conveyance rollers 23. The pickup roller 21 picks up sheets S from the supply tray 13 and conveys the sheets S toward the conveyance path 17. The separation roller 22 separates the sheets S picked up by the pickup roller 21 one by one. The plurality of conveyance rollers 23 guide the sheets S, which are separated by the separation roller 22, along the conveyance path 17, sequentially passing them through the process engine 4 and the fixing device 5, and discharging them to the discharge tray 15. The conveyance mechanism 3 rotates each roller based on the drive of a main motor (not shown) provided within the main housing 2.

The conveyance mechanism 3 includes multiple switchback rollers 25 and a reverse conveyance path 27 for reversing a sheet S printed on one side. The printer 10 is equipped with a flapper 28, positioned downstream of the fixing device 5 along the conveyance path 17. By oscillating the flapper 28, the printer 10 can switch the destination of the sheet S between the discharge tray 15 and the reverse conveyance path 27, indicated by the broken lines in FIG. 1. The conveyance mechanism 3 moves the flapper 28 to the position indicated by the two-dot chain line and rotates the switchback rollers 25 based on the drive of the main motor, thereby transporting the sheet S upward along the reverse conveyance path 27. Once the sheet S has been transported upward, the conveyance mechanism 3 reverses the rotation of the switchback rollers 25 to move the sheet S in the opposite direction along the reverse conveyance path 27. The sheet S is then conveyed past the bottom of the supply tray 13 to the front side of the printer. This process reverses the sheet S and transports the same to a base end of the conveyance path 17. The printer 10 performs duplex printing by executing printing on an upper surface of the reversed sheet S, which is the side opposite to a first printed surface. Additionally, the printer 10 has a function can execute printing even when the rear cover 12 is left open, allowing printed sheets S to be discharged onto the opened rear cover 12.

The process engine 4 forms an image on the sheet S by transferring a toner image onto the sheet S. The process engine 4 includes a laser unit 31, a drum unit 32, four developing cartridges 33Y, 33M, 33C, and 33K, and a transfer unit 34.

The laser unit 31 is positioned in the upper part of the main housing 2 and is configured to emit laser beam, indicated by the one-dot chain line, onto the surfaces of the multiple photoconductor drums 41 of the drum unit 32 to expose them. Details of the laser unit 31 will be described later.

The drum unit 32 is positioned between the supply tray 13 and the laser unit 31 within the main housing 2. The drum unit 32 includes four photoconductor drums 41, four chargers 43, and a support frame 45 that supports the photoconductor drums 41 and other components. The drum unit 32 is detachable from the main housing 2 when the front cover 11 is open.

The developing cartridges 33Y, 33M, 33C, and 33K correspond to the four colors yellow (Y), magenta (M), cyan (C), and black (K), respectively. They are detachably mounted on the drum unit 32 in this order, from the front to the rear of the printer 10. Each of the developing cartridges 33Y, 33M, 33C, and 33K includes a developing roller 51, a supply roller 52, and a toner storage section 53. Although the four developing cartridges 33Y, 33M, 33C, and 33K differ in toner color, their other configurations are identical. Accordingly, when referring collectively to the four developing cartridges corresponding to the respective colors, they are denoted simply as developing cartridges 33. Similarly, for other devices corresponding to the colors yellow, magenta, cyan, and black (e.g., the semiconductor laser 77), the present specification may use the alphabetic suffixes Y, M, C, and K after their reference numerals for individual descriptions or omit the suffixes when referring to them collectively.

The transfer unit 34 is positioned between the supply tray 13 and the drum unit 32 within the main housing 2. It includes a drive roller 61, a driven roller 62, a conveyance belt 63, and four transfer rollers 64. The conveyance belt 63 is stretched between the drive roller 61 and the driven roller 62, with its upper surface in contact with the photoconductor drums 41. The four transfer rollers 64 are arranged inside the conveyance belt 63 so that the belt is sandwiched between each transfer roller 64 and the corresponding photoconductor drum 41.

The charger 43 is positioned above the photoconductor drum 41 and is, for example, a scorotron-type charger equipped with a charging wire and a grid. The process engine 4 generates corona discharge through the charger 43 to uniformly positively charge the surface of the photoconductor drum 41. The laser unit 31 emits laser beams to expose the surface of the photoconductor drum 41, forming an electrostatic latent image on the drum's surface based on image data. Note that the device for charging the photoconductor drum 41 is not limited to a scorotron-type charger and may alternatively be a roller-type charging roller or another device. Furthermore, the charging polarity of the photoconductor drum 41 is not limited to positive charging and may also be negative charging.

The process engine 4 supplies toner from the toner storage section 53 to the supply roller 52, which then supplies the toner to the developing roller 51. The toner supplied to the developing roller 51 is carried onto the surface of the developing roller 51 as it rotates.

The developing roller 51 is rotated by the transmission of rotational drive force from the main motor. It supplies toner to the photoconductor drum 41, develops the electrostatic latent image formed on the surface of the photoconductor drum 41, and forms a toner image on its surface.

The toner carried on the developing roller 51 moves to the electrostatic latent image on the photoconductor drum 41 due to the potential difference between the developing roller 51 and the electrostatic latent image, thereby forming a toner image. This toner image is transferred onto the sheet S in the conveyance path 17 by applying a negative voltage to the transfer roller 64 while the photoconductor drum 41 is in contact with the sheet S.

The fixing device 5 is positioned within the main housing 2, located behind the process engine 4. The sheet S, onto which the toner image has been transferred, is conveyed to the fixing device 5. The fixing device 5 includes a heating roller 67 that heats the sheet S and a pressure unit 68 that sandwiches the sheet S between itself and the heating roller 67. The heating roller 67 contains a heater 69 inside, which heats the roller. The pressure unit 68 consists of an endless belt, a pressure pad that presses the endless belt against the heating roller 67, a holder that supports the pressure pad, and a belt guide. The pressure unit 68 rotates by transmitting rotational drive force from the main motor, pressing the sheet S against the heating roller 67 to apply pressure to the sheet S. Through this process, the fixing device 5 fixes the toner image onto the sheet S.

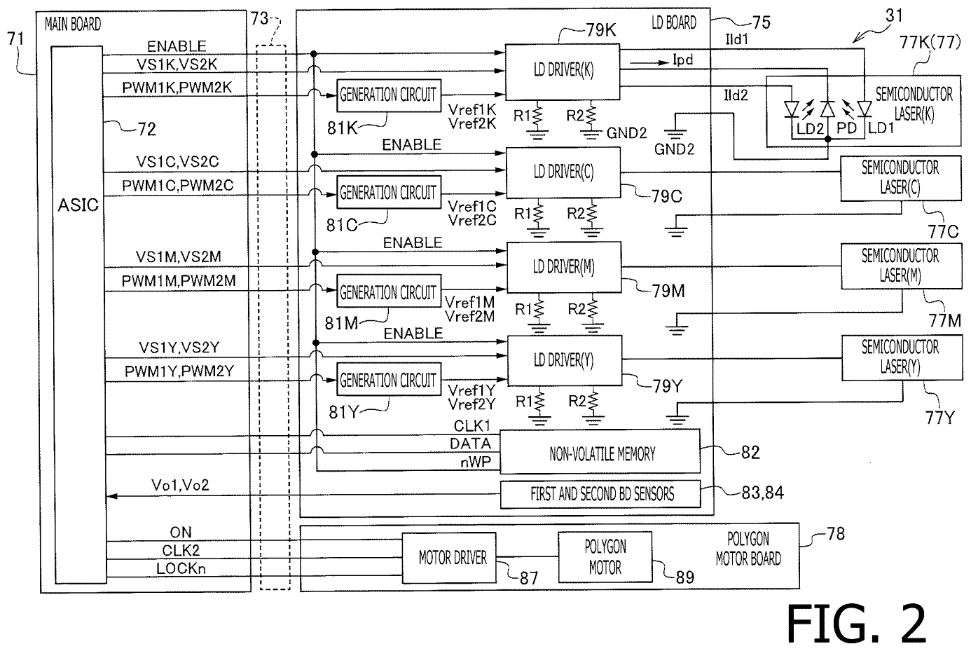

As shown in FIG. 2, the printer 10 includes a main board 71 that controls the laser unit 31. The main board 71 includes an ASIC 72. The ASIC 72 is an Application-Specific Integrated Circuit and contains a CPU and other components. The ASIC 72 reads and executes a control program from a storage device (such as RAM or ROM, not shown in the drawings) and performs centralized control of the printer 10. Note that the configuration of the main board 71 shown in FIG. 2 is merely an example. For instance, the main board 71 may include an SoC (System on a Chip) as the controller instead of the ASIC.

The main board 71 is connected to the laser unit 31 via a harness 73. The harness 73 is, for example, a flexible flat cable. The main board 71 controls the operation of the laser unit 31 through the harness 73.

The laser unit 31 includes an LD board 75, four semiconductor lasers 77Y, 77M, 77C, and 77K corresponding to different colors, and a polygon motor board 78. The LD board 75 includes four LD drivers 79Y, 79M, 79C, and 79K, each corresponding to a different color, four generation circuits 81Y, 81M, 81C, and 81K, a non-volatile memory 82, a first BD sensor 83, and a second BD sensor 84. The LD driver 79 is a driver circuit that causes the semiconductor laser 77 to emit light. The generation circuit 81 is a circuit that generates reference voltages Vref1 and Vref2, which are output to the LD driver 79. Details of the LD driver 79 and the generation circuit 81 will be described later.

The non-volatile memory 82 is a rewritable memory, such as an EEPROM (Electrically Erasable Programmable Read-Only Memory). The non-volatile memory 82 is not limited to an EEPROM and may instead be another type of non-volatile memory, such as flash memory or an EPROM. The non-volatile memory 82 stores correction data used for image formation. Specifically, it stores correction data for adjusting the light emission amount of the semiconductor laser 77 by modifying a duty cycle of the pulse width modulation (PWM) signals, PWM1 and PWM2, which will be described later. Additionally, the information stored in the non-volatile memory 82 is not limited to correction data; it may also include the serial number of the printer 10, log data recording the operational state of the printer 10, or other relevant information.

The non-volatile memory 82 receives a clock signal CLK1, a data signal DATA, and a write-protect signal nWP from the ASIC 72 via the harness 73. The clock signal CLK1 is a synchronization signal that synchronizes the timing of data writing to or reading from the non-volatile memory 82. The data signal DATA represents the data to be written to or read from the non-volatile memory 82. The write-protect signal nWP is a control signal that indicates whether writing to the non-volatile memory 82 is prohibited.

For example, the non-volatile memory 82 allows writing when the write-protect signal nWP is at a high level and prohibits writing when the write-protect signal nWP is at a low level. In the printer 10 of this embodiment, the wiring in the harness 73 for transmitting the write-protect signal nWP is shared with the wiring that transmits the enable signal ENABLE. This configuration reduces the number of wires in the harness 73, thereby decreasing the number of connections between the main board 71 and the LD board 75. However, the wiring for the write-protect signal nWP and an enable signal ENABLE may also be configured as separate lines.

The enable signal ENABLE is a control signal that switches the LD driver 79 between an active state and a stopped state. For example, the LD driver 79 operates when a high-level enable signal ENABLE is input and stops operating when a low-level enable signal ENABLE is input. In the printer 10 of this embodiment, the four LD drivers 79Y, 79M, 79C, and 79K share the wiring used to receive the enable signal ENABLE from the ASIC 72. Specifically, the enable signal ENABLE is output from a single output terminal of the ASIC 72, transmitted through a shared wiring in the harness 73, and then distributed to the four LD drivers 79Y, 79M, 79C, and 79K via the wiring pattern on the LD board 75. Thus, in this embodiment, not only is the wiring for the write-protect signal nWP and the enable signal ENABLE shared, but the wiring for the enable signal ENABLE to the four LD drivers 79Y, 79M, 79C, and 79K is also shared, reducing the overall number of wires. However, the enable signal ENABLE for the four LD drivers 79Y, 79M, 79C, and 79K may also be transmitted through separate lines.

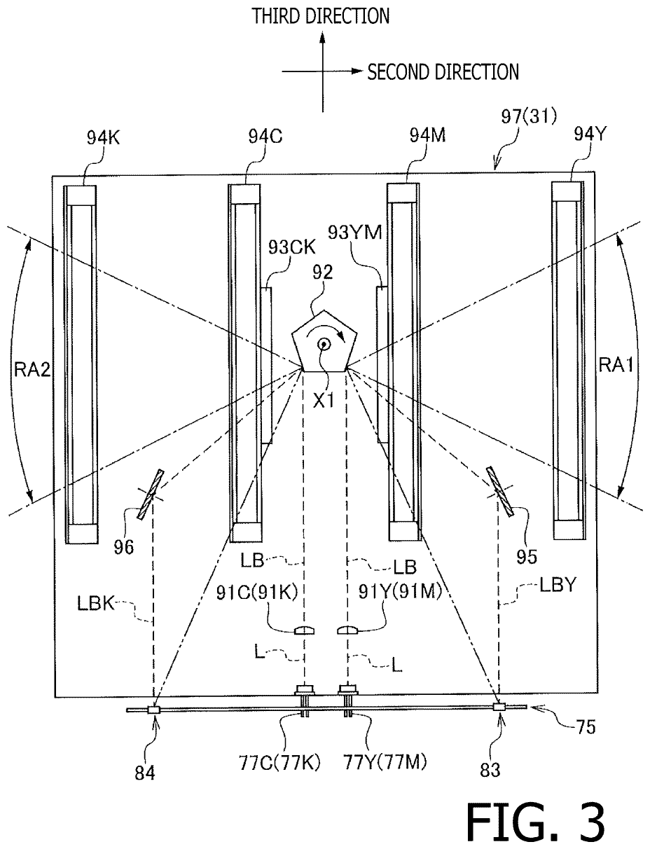

The LD driver 79 and the semiconductor laser 77 for each color have the same configuration. Therefore, in the following description, they will be collectively referred to as the LD driver 79 and the semiconductor laser 77. As shown in FIG. 2, the semiconductor laser 77 includes a first laser diode LD1, a second laser diode LD2, and a photodiode PD. FIG. 2 illustrates these components only for the black semiconductor laser 77K. The semiconductor laser 77 is designed as a unit where the first and second laser diodes LD1 and LD2 and the photodiode PD are housed inside a cap and electrically connected to the LD board 75. The first and second laser diodes LD1 and LD2 are, for example, an edge-emitting type laser diode that emit laser beams from both ends of the element. The first laser diode LD1 emits a laser beam L from a face facing the polygon mirror 92 (i.e., an upper face in FIG. 3) and emits a back laser beam (not shown) from the opposite facet. The second laser diode LD2 has the same structure as the first laser diode LD1. The photodiode PD is positioned within the unit so that it can receive the back laser beams from both the first and second laser diodes LD1 and LD2.

The first and second laser diodes LD1 and LD2 may be configured as separate units. In this case, a separate photodiode PD may be provided to receive the back laser beam from each of the laser diodes, with one photodiode receiving the back laser beam from LD1 and another receiving the back laser beam from LD2. It should be noted that the first and second laser diodes LD1 and LD2 are examples of the semiconductor laser according to aspects of the present disclosure. The semiconductor laser in the present disclosure is not limited to the edge-emitting type laser diode and may also be a surface-emitting type laser diode. Furthermore, the element that receives laser beams such as back laser beams is not limited to a photodiode and may be another light-receiving element capable of converting light into electrical signals, such as a CMOS image sensor.

The polygon motor board 78 includes a motor driver 87 and a polygon motor 89. The polygon motor board 78 is connected to the main board 71 via the harness 73. The harness 73 that connects the LD board 75 to the main board 71 may be separate from the harness 73 that connects the polygon motor board 78 to the main board 71. The motor driver 87 receives an ON signal ON, a clock signal CLK2, and a LOCKn signal LOCKn from the ASIC 72 on the main board 71 via the harness 73. The ON signal ON is a signal that switches the motor driver 87 between an active state and a stopped state.

The polygon motor 89 is, for example, a DC brushless motor. The motor driver 87 includes multiple switching elements that control the current supplied to the windings of the polygon motor 89. The clock signal CLK2 is a control signal used to switch the motor driver's switching elements on and off. When the motor driver 87 receives a high-level ON signal ON, it activates its circuits and controls the switching elements based on the clock signal CLK2. This causes the polygon motor 89 to start rotating. The ASIC 72 can control the rotation speed of the polygon motor 89 by adjusting the frequency of the clock signal CLK2. Additionally, when the motor driver 87 receives a low-level ON signal ON, it stops all circuits and ceases operation. The motor driver 87 may also be provided on the main board 71.

The LOCKn signal LOCKn indicates whether the polygon motor 89 has reached a particular rotation state (e.g., specific rotation count or speed). For example, the motor driver 87 outputs a high-level LOCKn signal LOCKn to the ASIC 72 until the rotation count per unit time of the polygon motor 89 reaches a preset value. Once the motor driver 87 detects that the rotation count per unit time has reached the particular value, the motor driver 87 outputs a low-level LOCKn signal LOCKn to the ASIC 72. The LOCKn signal LOCKn may also indicate whether the motor's rotation speed has reached a specified value.

FIG. 3 is a top view of the laser unit 31, illustrating paths of the beams emitted from the semiconductor lasers 77 until they reach the first and second BD sensors 83 and 84. As shown in FIG. 3, the laser unit 31 includes four collimator lenses 91 (i.e., 91Y, 91M, 91C, and 91K) (which may also be referred to as coupling lenses), a polygon mirror 92, two fθ lenses 93 (i.e., 93YM and 93CK) (which may also be referred to as scanning lenses), four reflection mirrors 94 (i.e., 94Y, 94M, 94C, and 94K) corresponding to each color, a first mirror 95, a second mirror 96, and a frame 97. The collimator lenses 91, polygon mirror 92, fθ lenses 93, reflection mirrors 94, and the first and second mirrors 95 and 96 are mounted on the frame 97.

In the following description, a direction parallel to a rotational axis X1 of the polygon mirror 92 (perpendicular to the plane of FIG. 3) is referred to as a “first direction.” The direction perpendicular to the first direction and parallel with a direction in which the polygon mirror 92 and fθ lenses 93YM and 93CK are aligned (a left-right direction in FIG. 3) is referred to as a “second direction.” Further, a direction perpendicular to both the first and second directions is referred to as a “third direction.” The third direction corresponds to the main scanning direction, while the first direction corresponds to the sub-scanning direction. The arrows indicating the first, second, and third directions in each of the drawings represent only one of the two opposite directions.

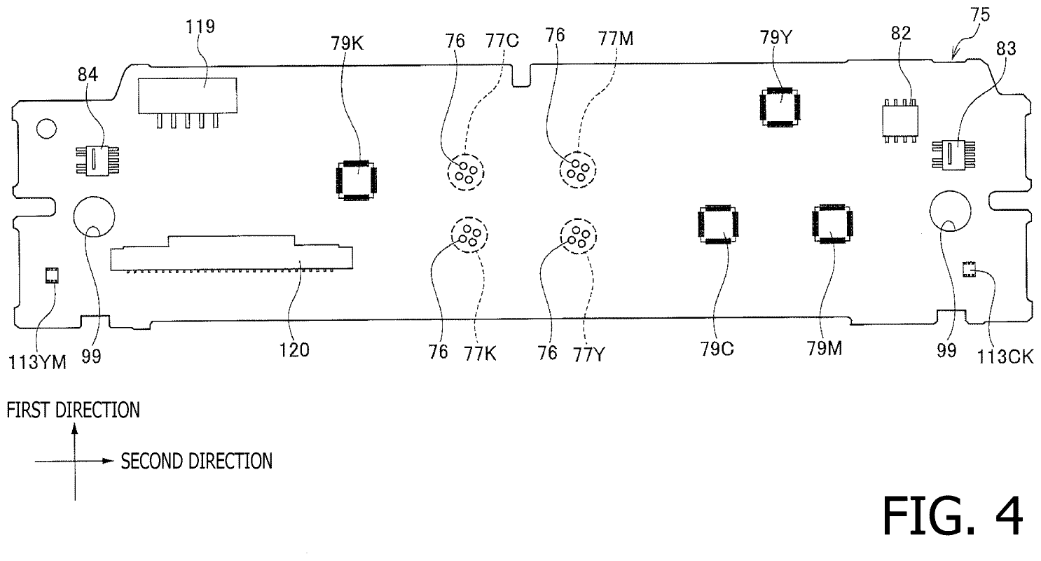

The frame 97 has a box-shaped structure, which forms a rectangular shape when viewed in a planar view along the first direction. The LD board 75 is mounted on the side surface of the frame 97 in the third direction. The LD board 75 is fixed to the frame 97 with screws (not shown) inserted into screw holes 99 (see FIG. 4), with its plane parallel to the first and second directions.

FIG. 4 is a plan view of the LD board 75, showing the surface on which the LD driver 79 is mounted. The surface shown in FIG. 4 is the outer surface in the third direction (the lower side in FIG. 3). The LD board 75 has a substantially rectangular shape with its longer side extending in the second direction. The second direction is an example of a particular direction according to aspects of the present disclosure.

As shown in FIGS. 3 and 4, the four semiconductor lasers 77 are mounted on the opposite surface from the LD driver 79, positioned at a central part in both the first and second directions. FIG. 4 represents the semiconductor lasers 77 on the opposite surface with dashed lines, while the lead insertion holes 76 for the semiconductor lasers 77 are indicated with solid lines. The multiple lead insertion holes 76 are arranged in groups of four, corresponding to the four leads of each semiconductor laser 77.

The four semiconductor lasers 77 are arranged surrounding a central part of the LD board 75. The semiconductor lasers 77C and 77K are aligned along the first direction with a particular spacing therebetween. Similarly, the semiconductor lasers 77M and 77Y are also aligned along the first direction with a particular spacing therebetween. Additionally, the semiconductor lasers 77C and 77M are aligned along the second direction with a particular spacing therebetween, while the semiconductor lasers 77K and 77Y are also aligned along the second direction with a particular spacing therebetween. The spacing between each semiconductor laser 77 in the first direction is narrower than the spacing in the second direction.

Each of the four collimator lenses 91 is positioned to face the corresponding semiconductor laser 77 in the third direction. The polygon mirror 92, collimator lenses 91, and semiconductor lasers 77 are arranged along the third direction. The collimator lenses 91 convert the laser beams L emitted from the semiconductor lasers 77 into beams LB and direct them toward the polygon mirror 92.

In the following description, to avoid complexity, the beam(s) LB may sometimes be referred to as laser beam(s) L. For example, the laser beam L emitted from the semiconductor laser 77 toward the polygon mirror 92 refers to beam LB, which is generated by the semiconductor laser 77, transformed by the collimator lens 91, and emitted toward the polygon mirror 92.

The above optical system configuration is merely an example. The laser unit 31 may also include components such as aperture plates or condenser lenses through which the laser beams L pass.

The laser unit 31 converts the laser beam L emitted from the semiconductor laser 77 into beam LB and irradiates the photoconductor drum 41 of the developing cartridge 33 by directing the beam LB, which has been deflected by the polygon mirror 92.

The polygon mirror 92 is a rotating multi-faceted mirror, which, for example, has the shape of a regular pentagonal prism with five reflective surfaces forming its side faces. The polygon mirror 92 is rotationally driven by the polygon motor 89 and deflects the laser beam L emitted from the semiconductor laser 77. For example, the polygon mirror 92 rotates in a clockwise direction in FIG. 3, deflecting the beam LB, which enters from the collimator lens 91, along the main scanning direction.

The fθ lenses 93 focus the beams LB that have been scanned by the polygon mirror 92. The fθ lenses 93 collect the beams LB emitted from the collimator lenses 91 and reflected by the reflective surfaces of the polygon mirror 92. The reflection mirrors 94 are provided for each color and are arranged in a row along the second direction. As shown in FIG. 3, the four reflection mirrors 94 are aligned in the order of 94Y, 94M, 94C, and 94K from one side (e.g., from the right-hand side in FIG. 3) in the second direction and are equally spaced along the second direction.

The polygon mirror 92 is positioned in the second direction between the reflection mirrors 94C and 94M, equidistant from both mirrors. The fθ lens 93YM is shared for the beams LB of the semiconductor lasers 77Y and 77M and is positioned between the reflection mirror 94M and the polygon mirror 92 in the second direction. Similarly, the fθ lens 93CK is shared for the beams LB of the semiconductor lasers 77C and 77K and is positioned between the reflection mirror 94C and the polygon mirror 92 in the second direction.

The four reflection mirrors 94 are mounted at different positions and orientations in the first direction, for example, and they direct the beams LB, which are emitted from each of the four semiconductor lasers 77 and focused by the fθ lenses 93, onto the surface of the corresponding photoconductor drum 41 for each color. As a result, the optical path length from each semiconductor laser 77 to the photoconductor drum 41 differs for each color. As the polygon motor 89 rotates, the polygon mirror 92 also rotates, causing the angle of the reflective surface relative to the emission direction of the beam LB from the collimator lens 91 to change periodically. Consequently, the beam LB is periodically deflected by the reflective surface of the polygon mirror 92, forming a scanning line on the surface of the photoconductor drum 41.

The first BD sensor 83 and the second BD sensor 84 are positioned at both ends of the LD board 75 in the second direction. The first BD sensor 83 is located at the right end of the LD board 75 in FIG. 4 and is positioned in the first direction with a screw hole 99 in between, opposite to the linear regulator 113CK. Similarly, the second BD sensor 84 is located at the left end of the LD board 75 in FIG. 4 and is positioned in the first direction with a screw hole 99 in between, opposite to the linear regulator 113YM, which will also be described later.

The LD drivers 79Y, 79M, and 79C are positioned in the second direction between the semiconductor lasers 77Y and 77M and the first BD sensor 83 (including the screw hole 99 and the linear regulator 113CK). The LD drivers 79Y, 79M, and 79C are arranged at positions corresponding to the vertices of an equilateral triangle.

Additionally, the non-volatile memory 82 is located in the second direction between the LD driver 79Y and the first BD sensor 83.

The LD driver 79K corresponding to black is positioned in the second direction between the semiconductor lasers 77C and 77K and the second BD sensor 84, closer to the semiconductor laser 77C. In other words, the LD driver 79K corresponding to black is positioned in the second direction on the opposite side of the four semiconductor lasers 77 from the other color LD drivers 79Y, 79M, and 79C. Additionally, the linear regulator 113YM corresponding to black is positioned in the second direction on the opposite side of the four LD drivers 79 and the four semiconductor lasers 77 from the linear regulator 113CK. Each of the linear regulators 113YM and 113CK is located at the end of the LD board 75 in the second direction.

In the second direction, a first connector 119 and a second connector 120 are positioned between the second BD sensor 84 and the LD driver 79K. The first connector 119 is used to connect the LD board 75 and the polygon motor board 78. The second connector 120 is used to connect the harness 73. The second connector 120 is connected to the main board 71 via the harness 73 and is used for input and output of signals such as the enable signal ENABLE mentioned above.

As shown in FIGS. 3 and 4, the first BD sensor 83 is a sensor configured to detect the beam LBY corresponding to yellow among the beams LB deflected by the polygon mirror 92. The first BD sensor 83 is fitted into the LD board 75 and exposed on both sides of the LD board 75. The detection surface of the first BD sensor 83 faces the frame 97. The first mirror 95 is positioned in the third direction between the polygon mirror 92 and the first BD sensor 83. When the reflective surface of the polygon mirror 92 is at a specific angle, the first mirror 95 reflects the beam LBY, which has been emitted from the polygon mirror 92 via the fθ lens 93YM, toward the first BD sensor 83. Additionally, the first effective scanning range RA1 shown in FIG. 3 represents the scanning range used for image formation with the beam LBY corresponding to yellow, while the second effective scanning range RA2 represents the scanning range used for image formation with the beam LBK corresponding to black.

The first BD sensor 83 includes, for example, a photodiode and a comparator circuit. The first BD sensor 83 is configured to output a high-level detection signal Vo1 (see FIG. 2) when the amount of received light from the beam LBY on the photodiode is below a particular threshold and a low-level detection signal Vo1 when the received light amount exceeds the threshold. The first BD sensor 83 outputs a detection signal Vo1 to the ASIC 72 on the main board 71 via the harness 73. Based on the detection signal Vo1 from the first BD sensor 83, the ASIC 72 detects the particular timing after the writing of the beam LBY onto the photoconductor drum 41 corresponding to yellow has been completed.

The second BD sensor 84 and the second mirror 96 have the same configuration as the first BD sensor 83 and the first mirror 95. Therefore, a detailed explanation of the second BD sensor 84 and the second mirror 96 is omitted. Similar to the first BD sensor 83, the second BD sensor 84 receives the beam LBK, which is emitted from the polygon mirror 92 through the fθ lens 93CK when the reflective surface of the polygon mirror 92 is at a specific angle and is then reflected by the second mirror 96. The second BD sensor 84 outputs a detection signal Vo2 to the ASIC 72 based on the received light amount of the beam LBK.

As shown in FIG. 2, the ASIC 72 is configured to output video signals VS1 and VS2 to each of the four LD drivers 79 via the harness 73. These video signals VS1 and VS2 are signals that switch the emission state of the semiconductor laser 77, that is, the video signals VS1 and VS2 control the exposure state, as will be described later. For example, the ASIC 72 adjusts the video signals VS1 and VS2 output to each LD driver 79 based on the time when the beam LBK is detected by the second BD sensor 84, thereby controlling the timing at which the LD board 75 causes the semiconductor laser 77 to start exposing the photoconductor drum 41. By determining a write start position for each color image according to the timing at which the beam LBK reaches the second BD sensor 84, this configuration reduces positional misalignment when generating the electrostatic latent image on each photoconductor drum 41.

The ASIC 72 performs correction for thermal expansion of the laser unit 31 (including the frame 97 and lenses) based on the detection signals Vo1 and Vo2 from the first and second BD sensors 83 and 84. For example, the ASIC 72 calculates a correction value related to thermal expansion based on the detection timing of the first BD sensor 83 and the second BD sensor 84 and executes corrections such as adjustments to the write timing. Alternatively, the printer 10 may be configured to include only one of the first BD sensor 83 or the second BD sensor 84.

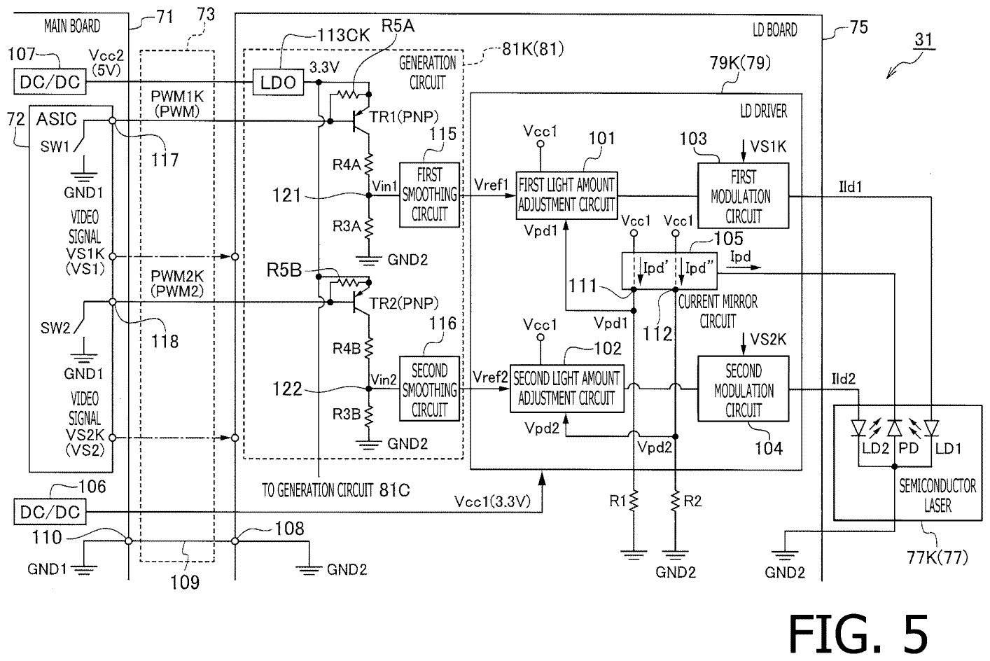

FIG. 5 shows a circuit diagram of the LD board 75. FIG. 5 illustrates only the LD driver 79K and the generation circuit 81K out of the four LD drivers 79 and four generation circuits 81.

The LD drivers 79 and generation circuits 81 for the other colors have the same configuration as the LD driver 79K and the generation circuit 81K. Therefore, in the following description, each circuit will be referred to as the LD driver 79 and the generation circuit 81.

As shown in FIGS. 2 and 5, the LD driver 79 includes a first light amount adjustment circuit 101, a second light amount adjustment circuit 102, a first modulation circuit 103, a second modulation circuit 104, and a current mirror circuit 105. Based on the video signals VS1 and VS2 input from the ASIC 72, the LD driver 79 switches the first and second laser diodes LD1 and LD2 of the semiconductor laser 77 between an emission state and an off state. The second light amount adjustment circuit 102, the second modulation circuit 104, and the second laser diode LD2 have the same configuration as the first light amount adjustment circuit 101, the first modulation circuit 103, and the first laser diode LD1. Therefore, in the following description, the focus will be on the first light amount adjustment circuit 101, the first modulation circuit 103, and the first laser diode LD1, while explanations regarding the second light amount adjustment circuit 102, the second modulation circuit 104, and the second laser diode LD2 will be omitted as necessary.

The main board 71 includes a DC/DC converter 106. The DC/DC converter 106 supplies, for example, a 3.3 V DC voltage to the LD driver 79 via the harness 73. The DC voltage output from the DC/DC converter 106 is supplied as the drive voltage Vcc1 to the first and second light amount adjustment circuits 101 and 102, as well as to the current mirror circuit 105. The first light amount adjustment circuit 101 receives a detection voltage Vpd1 from the current mirror circuit 105. The detection voltage Vpd1 corresponds to the magnitude of the photocurrent Ipd flowing through the photodiode PD when the first laser diode LD1 emits light. When the photodiode PD receives back laser beams, a photocurrent Ipd is generated. The photocurrent Ipd is a current that varies according to the amount of back laser beams received by the photodiode PD.

The LD board 75 includes an LD reference potential section (which may also be referred to as an LD ground) GND2, which is configured to provide a reference potential for the LD driver 79, the generation circuit 81, and the semiconductor laser 77. The photocurrent Ipd flows from the cathode of the photodiode PD through the anode toward the LD ground GND2. Additionally, the main board 71 includes a main reference potential section (which may also be referred to as a main ground) GND1, which serves as the reference potential for the ASIC 72, the DC/DC converter 106, and the DC/DC converter 107. The ground terminal 108 on the LD board 75 is connected to the ground terminal 110 on the main board 71 via the ground wire 109 included in the harness 73. As a result, the LD ground GND2 of the LD board 75 is connected to the main ground GND1 of the main board 71 via the ground wire 109.

The current mirror circuit 105 is connected to the cathode of the photodiode PD and replicates (copies) the photocurrent Ipd flowing through the photodiode PD, outputting the replicated photocurrent from the first and second output terminals 111 and 112. The first output terminal 111 is connected to the first light amount adjustment circuit 101 and outputs the detection voltage Vpd1 to the first light amount adjustment circuit 101. Additionally, the first output terminal 111 is connected to the LD ground GND2 via a fixed resistor R1. Similarly, the second output terminal 112 is connected to the second light amount adjustment circuit 102 and outputs the detection voltage Vpd2 to the second light amount adjustment circuit 102. Additionally, the second output terminal 112 is connected to the LD ground GND2 via a fixed resistor R2.

When the first laser diode LD1 emits light, the current mirror circuit 105 causes a current Ipd′ to flow from the terminal receiving the drive voltage Vcc1 through the fixed resistor R1 to the LD ground GND2. This current Ipd′ corresponds to the photocurrent Ipd. As a result, a detection voltage Vpd1 (=R1×Ipd′) is generated between the LD ground GND2 and the fixed resistor R1 due to the flow of the current Ipd′. Therefore, the detection voltage Vpd1 varies according to the resistance value of the fixed resistor R1.

The first light amount adjustment circuit 101 receives the detection voltage Vpd1, which corresponds to the amount of light received by the photodiode PD when the first laser diode LD1 emits light. Based on the detection voltage Vpd1, the first light amount adjustment circuit 101 adjusts the light emission amount of the first laser diode LD1. In each color LD driver 79, a fixed resistor R1 is connected between the first light amount adjustment circuit 101 and the LD ground GND2.

As shown in FIG. 3, the optical path length of the laser beam L varies for each color. Additionally, the number of lenses the laser beam L passes through or reflects off differs depending on the color. Therefore, for example, during the manufacturing of the printer 10, the resistance value of the fixed resistor R1 can be adjusted according to the optical path length and the number of lenses for each color. This allows the first light amount adjustment circuit 101 to regulate the light emission amount of the first laser diode LD1 based on the resistance value of the fixed resistor R1, enabling color-specific adjustment.

Similarly, when the second laser diode LD2 emits light, the current mirror circuit 105 causes a current Ipd″ to flow from the terminal receiving the drive voltage Vcc1 through the fixed resistor R2 to the LD ground GND2. This current Ipd″ corresponds to the photocurrent Ipd. As a result, a detection voltage Vpd2 is generated between the LD ground GND2 and the fixed resistor R2 due to the flow of the current Ipd″. The detection voltage Vpd2 varies according to the resistance value of the fixed resistor R2. The second light amount adjustment circuit 102 receives the detection voltage Vpd2, which corresponds to the amount of light received by the photodiode PD when the second laser diode LD2 emits light.

The first light amount adjustment circuit 101 is an Automatic Power Control (APC) circuit that adjusts the light emission amount of the laser beam L emitted by the first laser diode LD1. The first light amount adjustment circuit 101 includes a comparator and receives a reference voltage Vref1. The comparator compares the detection voltage Vpd1 with the reference voltage Vref1 and controls the current flow so that the voltage value of the detection voltage Vpd1 matches the reference voltage Vref1. The first light amount adjustment circuit 101 is connected to the anode of the first laser diode LD1 via the first modulation circuit 103.

During image formation and during the adjustment of the light emission amount, a current Ild1 flows from the anode of the first laser diode LD1 through the cathode toward the LD ground GND2.

The current Ild1 is adjusted by the first light amount adjustment circuit 101 based on the detection voltage Vpd1, thereby controlling the light emission amount of the first laser diode LD1.

Specifically, the first light amount adjustment circuit 101 operates as follows:
(a) When the reference voltage Vref1 is greater than the detection voltage Vpd1, it increases the current Ild1.
(b) When the reference voltage Vref1 is less than the detection voltage Vpd1, it decreases the current Ild1.

The first light amount adjustment circuit 101 applies feedback control to adjust the current Ild1 so that the detection voltage Vpd1 always matches the reference voltage Vref1.

The second light amount adjustment circuit 102 is connected to the anode of the second laser diode LD2 via the second modulation circuit 104. Similar to the first light amount adjustment circuit 101, the second light amount adjustment circuit 102 compares the reference voltage Vref2 with the detection voltage Vpd2 and adjusts the current Ild2 flowing through the second laser diode LD2.

The first modulation circuit 103 turns the emission of the first laser diode LD1 on and off by switching the current Ild1 on and off based on the binary video signal VS1 input from the ASIC 72. Similarly, the second modulation circuit 104 turns the emission of the second laser diode LD2 on and off based on the video signal VS2 from the ASIC 72.

For example, during printing, the ASIC 72 modifies the video signals VS1 and VS2 based on image data, turning the first and second laser diodes LD1 and LD2 on and off to form an electrostatic latent image on the photoconductor drum 41. The printer 10 of the present embodiment is capable of performing simultaneous exposure using two laser diodes. Specifically, the first and second laser diodes LD1 and LD2 are positioned in an offset arrangement relative to each other. The laser beams L emitted from the first and second laser diodes LD1 and LD2 are reflected by the polygon mirror 92 at positions shifted in the rotation axis direction (first direction) of the polygon mirror 92. As a result, when rotating at high speed, the polygon mirror 92 periodically deflects the laser beams L emitted from the first and second laser diodes LD1 and LD2, forming two parallel scanning lines on the surface of the photoconductor drum 41 in a direction perpendicular to the rotation direction of the drum, i.e., in the main scanning direction.

Noted that the laser unit 31 may be configured to include only one laser diode or three or more laser diodes. Therefore, the number of light amount adjustment circuits, modulation circuits, and other components provided on the LD board 75 may be adjusted according to the number of laser diodes.

As shown in FIG. 5, the generation circuit 81 includes a linear regulator 113CK, a first transistor TR1, a second transistor TR2, first resistors R3A and R3B, second resistors R4A and R4B, a first smoothing circuit 115, and a second smoothing circuit 116. The first transistor TR1, along with the first and second resistors R3A and R4A, constitutes an example of the switching circuit according to aspects of the present disclosure. Similarly, the second transistor TR2, along with the first and second resistors R3B and R4B, also constitutes an example of the switching circuit according to aspects of the present disclosure. The main board 71 includes a DC/DC converter 107. The DC/DC converter 107 outputs a 5 V DC voltage Vcc2 to the linear regulator 113CK of the generation circuit 81 via the harness 73. The DC/DC converter 107 that supplies the 5 V DC voltage Vcc2 and the DC/DC converter 106 that supplies the 3.3 V DC voltage may be implemented as the same circuit. Additionally, the DC power supply provided on the main board 71 is not limited to a DC/DC converter; other DC power supplies, such as a linear regulator, may also be used.

The first transistor TR1 is a PNP transistor connected between the linear regulator 113CK and the second resistor R4A. The first transistor TR1, being a PNP transistor, is an example of the semiconductor transistor according to aspects of the present disclosure. Noted that the semiconductor transistor according to aspects of the present disclosure is not limited to a bipolar transistor such as a PNP transistor but may also be a field-effect transistor (FET).

The base of the first transistor TR1 is an example of a control terminal of the semiconductor transistor and serves as a terminal for controlling the operation of the semiconductor transistor. If the semiconductor transistor is an FET, its control terminal corresponds to the gate of the FET.

The emitter of the first transistor TR1 is an example of an input terminal of the semiconductor transistor, serving as a terminal through which current or voltage is input to the semiconductor transistor. If the semiconductor transistor is an FET, its input terminal corresponds to the source of the FET. Similarly, the collector of the first transistor TR1 is an example of an output terminal of the semiconductor transistor, serving as a terminal through which current or voltage is output from the semiconductor transistor. If the semiconductor transistor is an FET, its output terminal corresponds to the drain of the FET.

The emitter of the first transistor TR1 is connected to the output terminal of the linear regulator 113CK. The linear regulator 113CK is a low dropout voltage regulator. The linear regulator 113CK receives a 5 V DC voltage Vcc2 from the DC/DC converter 107. The linear regulator 113CK generates a 3.3 V DC voltage from the input DC voltage Vcc2 and outputs the generated DC voltage to the emitter of the first transistor TR1. The linear regulator 113CK is an example of the voltage generation circuit according to aspects of the present disclosure. It should be noted that the voltage generation circuit is not limited to a linear regulator and may also be implemented using other DC power sources such as a DC/DC converter.

The ASIC 72 includes a first output terminal 117, which is an open output. The first output terminal 117 is connected to the main ground GND1 in the ASIC 72 via a first switch SW1. The first output terminal 117 is also connected to the base of the first transistor TR1 on the LD board 75 via the harness 73. Additionally, the base of the first transistor TR1 is connected to the emitter of the first transistor TR1 via a resistor R5A.

When the first switch SW1 in the ASIC 72 is open (OFF), the first output terminal 117 and the main ground GND1 are electrically disconnected. Since no current flows from the linear regulator 113CK through the resistor R5A, the emitter and base of the first transistor TR1 are both applied with the same voltage. Specifically, the emitter and base of the first transistor TR1 are each applied with a voltage of 3.3 V referenced to the LD ground GND2. When the first switch SW1 in the ASIC 72 is closed (ON), the first output terminal 117 and the main ground GND1 are electrically connected. Current flows from the linear regulator 113CK through the resistor R5A. Consequently, the emitter of the first transistor TR1 is applied with a voltage of 3.3 V referenced to the LD ground GND2, while the base of the first transistor TR1 is applied with the voltage of the main ground GND1.

The ASIC 72 alternates the connection between the main ground GND1 and the first output terminal 117 by opening and closing the first switch SW1 at a particular frequency. This results in the first output terminal 117 outputting a pulse-width modulation (PWM) signal PWM1, where the voltage is 3.3 V referenced to the LD ground GND2 when open and the voltage of the main ground GND1 when closed. The voltage of the PWM signal PWM1 is applied to the base of the first transistor TR1 as a result of the ON/OFF switching of the first switch SW1 at the first output terminal 117.

The collector of the first transistor TR1 is connected to a second resistor R4A. One end of the second resistor R4A is connected to the collector, while the other end is connected to the LD ground GND2 via a first resistor R3A. Additionally, the connection portion 121, where the first and second resistors R3A and R4A are connected, is connected to the input terminal of the first smoothing circuit 115. A voltage is applied at the connection portion 121 of the first smoothing circuit 115 as an input voltage Vin1. The first smoothing circuit 115 smooths the input voltage Vin1 and outputs the smoothed voltage as a reference voltage Vref1 to the first light amount adjustment circuit 101.

The ASIC 72 changes the reference voltage Vref1 by opening (off) and closing (on) the first switch SW1 at a particular frequency.

### Characteristic Configuration of the First Embodiment

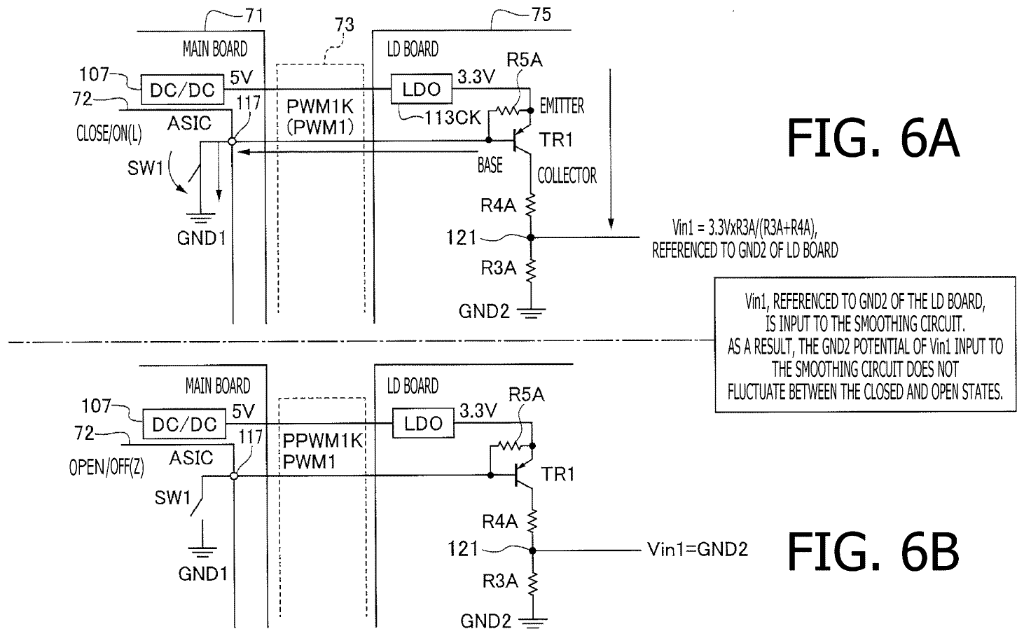

FIGS. 6A and 6B show a diagram illustrating the input voltage Vin1 output to the first smoothing circuit 115 by the circuit (i.e., the switching circuit) composed of the first transistor TR1 and the first and second resistors R3A and R4A in the first embodiment. As shown in FIG. 6A, when ASIC 72 turns on the first switch SW1 and connects the main ground GND1 to the first output terminal 117, current flows from the linear regulator 113CK through the emitter of the first transistor TR1 toward the main ground GND1 of ASIC 72. Since current can flow from the emitter to the collector of the first transistor TR1, the first transistor TR1 enters the on state. As described above, when the first transistor TR1 is in the on state, its emitter has a voltage of 3.3 V with reference to the LD ground GND2 of the LD board 75, while its base is supplied with the voltage of the main ground GND1.

Additionally, when the first transistor TR1 is on, current flows between the emitter and collector of the first transistor TR1, as well as through the first and second resistors R3A and R4A. Because the voltage drops across the first transistor TR1 is minimal, the voltage at its collector is effectively 3.3 V with reference to the LD ground GND2. Therefore, the voltage at the connection portion 121 (input voltage Vin1) with reference to the LD ground GND2 is the on-voltage, which is obtained by dividing the voltage applied to the emitter (collector) of the first transistor TR1 using the first and second resistors R3A and R4A. Specifically, the on-voltage is given by (3.3 V×R3A/(R3A+R4A)). The input voltage Vin1 is determined by the voltage generated by the linear regulator 113CK and the resistance values of the first and second resistors R3A and R4A. The first smoothing circuit 115 receives the input voltage Vin1 with reference to the LD ground GND2.

On the other hand, as shown in FIG. 6B, when ASIC 72 opens (turns off) the first switch SW1, disconnecting the main ground GND1 from the first output terminal 117, no current flows from the linear regulator 113CK through the emitter of the first transistor TR1 toward the main ground GND1. Consequently, no current flows from the emitter to the collector of the first transistor TR1, and the first transistor TR1 enters the off state.

As described above, when the first transistor TR1 is off, its emitter maintains a voltage of 3.3 V with reference to the LD ground GND2 of the LD board 75, and its base also retains a voltage of 3.3 V with reference to the LD ground GND2. Since the first transistor TR1 is in the off state, no current flows between its emitter and collector, and no current flows through the first and second resistors R3A and R4A. As a result, the voltage at the connection portion 121 (input voltage Vin1) becomes equal to the reference potential i.e., the LD ground GND2. This reference potential serves as the off voltage. The first smoothing circuit 115 receives this off voltage as its input.

The circuit including the first transistor TR1 and the first and second resistors R3A and R4A (switching circuit) alternately switches and outputs either an on-voltage, which is referenced to the LD ground GND2 and calculated as (3.3 V×R3A/(R3A+R4A)), or an off-voltage, which is the reference potential of the LD ground GND2, to the first smoothing circuit 115. The generation circuit 81 smooths the input voltage Vin1, which fluctuates (turns on and off) according to the duty cycle of the PWM signal PWM1, using the first smoothing circuit 115 to generate the reference voltage Vref1. The generated reference voltage (Vref1) is then output to the first light amount adjustment circuit 101. By adjusting the duty cycle of the PWM signal PWM1, ASIC 72 can modify the reference voltage Vref1 output from the generation circuit 81, thereby controlling the light emission amount of the first laser diode LD1.

### Comparative Example Configuration

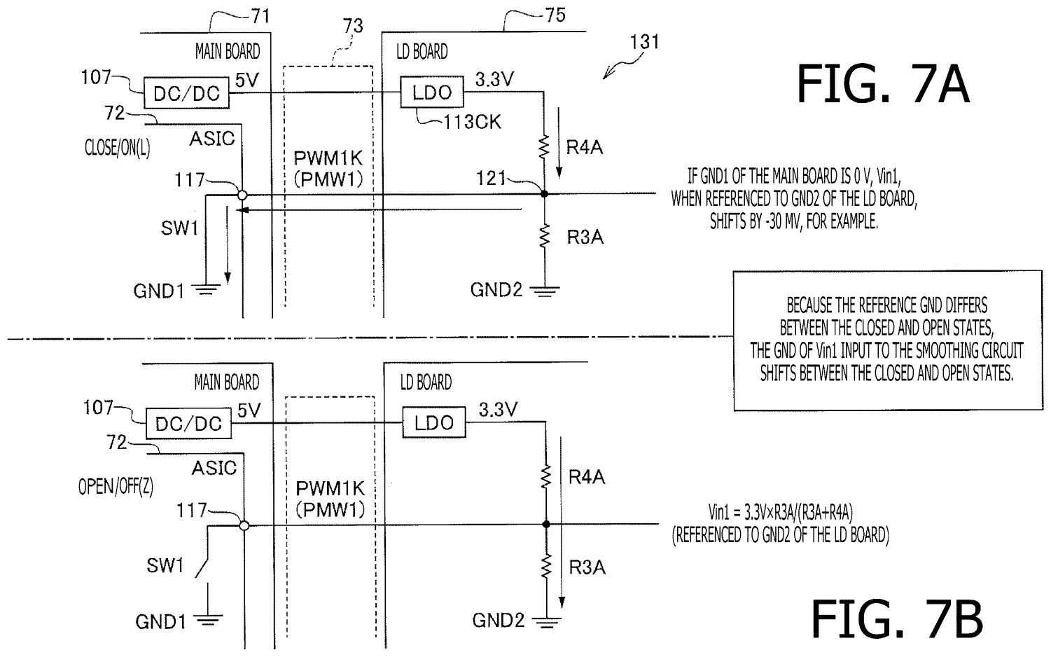

FIGS. 7A and 7B each shows an enlarged view of a portion of a generation circuit 131 in a comparative example that differs from the first embodiment. As shown in FIGS. 7A and 7B, in the comparative example, the generation circuit 131 does not include the first transistor TR1 on the high potential side of the second resistor R4A. Additionally, the first output terminal 117 of ASIC 72 is connected to the connection portion 121, which is the junction of the first and second resistors R3A and R4A. As shown in FIG. 7A, when ASIC 72 closes (turns on) the first switch SW1, current flows from the linear regulator 113CK to the main ground GND1 via the second resistor R4A. The input voltage Vin1 at the connection portion 121 becomes equal to the reference potential, i.e, the main ground GND1.

On the other hand, as shown in FIG. 7B, when ASIC 72 opens (turns off) the first switch SW1, no current flows from the linear regulator 113CK to the main ground GND1 via the second resistor R4A. In this case, the input voltage Vin1 is determined by dividing the 3.3 V voltage applied by the linear regulator 113CK using the first and second resistors R3A and R4A, resulting in Vin1 (=3.3 V×R3A/(R3A+R4A)). The input voltage Vin1 (=3.3 V×R3A/(R3A+R4A)) is a voltage referenced to the LD ground GND2.

### Comparison of Input Volage Between First Embodiment and Comparative Example

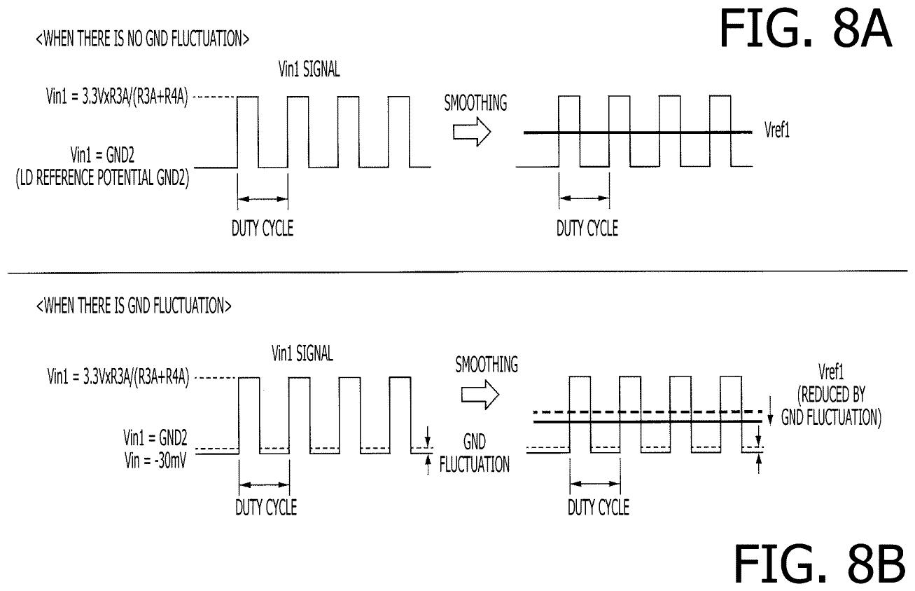

FIG. 8A illustrates the input voltage Vin1 applied to the first smoothing circuit 115 in the first embodiment and the reference voltage Vref1 output by the first smoothing circuit 115. FIG. 8B illustrates the input voltage Vin1 applied to the first smoothing circuit 115 in the comparative example and the reference voltage Vref1 output by the first smoothing circuit 115.

The LD ground GND2 is connected to the main ground GND1 of the main board 71 via the ground wire 109 included in the harness 73. If the physical distance between the main board 71 and the LD board 75 increases, the length of the harness 73, i.e., the length of the ground wire 109, also increases, resulting in a higher resistance value of the ground wire 109. Consequently, a potential difference may occur between the reference potential of the main ground GND1 and the reference potential of the LD ground GND2, potentially causing so-called ground floating (GND floating).

FIG. 8B illustrates the input voltage Vin1 in the case of the comparative example shown in FIGS. 7A and 7B. When ASIC 72 closes (turns on) the first switch SW1, the input voltage Vin1, when viewed with respect to the reference potential of the LD ground GND2, is based on a potential lowered by the power loss caused by the resistance value of the ground wire 109. For example, assuming the voltage based on the reference potential of the LD ground GND2 is 0 V, the input voltage Vin1 would be lowered by approximately 30 mV.

On the other hand, as shown in FIG. 8B, when the ASIC 72 opens (turns off) the first switch SW1, the input voltage Vin1 becomes a voltage based on the reference potential of the LD ground GND2, expressed as 3.3 V×R3A/(R3A+R4A). Therefore, as illustrated in FIG. 7B, when GND floating occurs, if the ASIC 72 closes (turns on) the first switch SW1, the input voltage Vin1 drops by approximately 30 mV from the voltage based on the reference potential of the LD ground GND2. As a result, in the comparative example shown in FIG. 8B, the smoothed reference voltage Vref1 becomes lower than the reference voltage Vref1 without GND floating, which is indicated by the dotted line.

As shown in FIG. 8A, in the generation circuit 81 of the first embodiment, the input voltage Vin1 based on the reference potential of the LD ground GND2 can be output in both cases: when the first switch SW1 is on (on voltage) and when it is off (off voltage). In other words, in this embodiment, both the on voltage and the off voltage can be matched to the reference potential of the LD ground GND2 without any GND deviation. This allows the desired input voltage Vin1 to be accurately output to the first smoothing circuit 115 as intended. The same applies to the reference voltage Vref2.

The second transistor TR2, the first resistor R3B, the second resistor R4B, and the second smoothing circuit 116 have the same configuration as the first transistor TR1, the first resistor R3A, the second resistor R4A, and the first smoothing circuit 115. Therefore, a detailed description is omitted. The base of the second transistor TR2 is connected to the first output terminal 118 of ASIC 72 via the harness 73. Additionally, the base of the first transistor TR1 is connected to the emitter of the first transistor TR1 via the resistor R5B. The first output terminal 118 is connected to the main ground GND1 via the second switch SW2. The collector of the second transistor TR2 is connected to the LD ground GND2 via the first resistor R3B and the second resistor R4B. ASIC 72 alternates the connection between the main ground GND1 and the first output terminal 118 by opening and closing the second switch SW2 at a particular frequency. As a result, the first output terminal 118 outputs a pulse-width modulation signal PWM2, where the voltage is 3.3 V referenced to the LD ground GND2 when open and the voltage of the main ground GND1 when closed.

The second transistor TR2, along with the first and second resistors R3B and R4B, constitutes an example of a switching circuit. The circuit (switching circuit) composed of the second transistor TR2 and the first and second resistors R3B and R4B outputs an input voltage Vin2 with a particular duty ratio from the connection portion 122 to the second smoothing circuit 116. The second smoothing circuit 116 smooths the input voltage Vin2 and outputs the smoothed input voltage Vin2 as the reference voltage (Vref2) to the second light amount adjustment circuit 102. As a result, ASIC 72 can modify the reference voltage (Vref2) output by the generation circuit 81 by adjusting the PWM signal PWM2, thereby controlling the light emission amount of the second laser diode LD2.

Additionally, the linear regulator 113CK is shared not only by the black generation circuit 81K but also by the cyan generation circuit 81C. Accordingly, the first transistor TR1 and the second transistor TR2 of the generation circuit 81C have their emitters connected to the linear regulator 113CK, receiving a supply of 3.3 V DC voltage. Furthermore, LD board 75 includes a linear regulator 113YM for yellow and magenta (see FIG. 4). The linear regulator 113YM supplies 3.3 V DC voltage to the emitters of the first transistor TR1 and the second transistor TR2 of both the yellow generation circuit 81Y and the magenta generation circuit 81M. It should be noted that the above-described configuration is merely an example. For instance, main board 71 may be configured to include a separate linear regulator 113 for each of the four generation circuits 81.

### Adjustment of Light Emission Amount

To ensure that the light emission amount of beam LB, emitted by semiconductor laser 77 and directed to photoconductor drum 41 via polygon mirror 92, remains within a particular range, it is necessary to adjust the light emission amount of the first and second laser diodes LD1 and LD2. During the execution of light emission amount adjustment, either the first laser diode LD1 or the second laser diode LD2 is selectively activated. Photodiode PD receives the back laser beam from either the first laser diode LD1 or the second laser diode LD2, causing a photocurrent Ipd to flow. As described above, fixed resistors R1 and R2, connected to each LD driver 79, are adjusted according to the optical path distance of each laser beam L. By adjusting the resistance values of fixed resistors R1 and R2 and thereby adjusting detection voltages Vpd1 and Vpd2, the light emission amount can be individually adjusted for each color and laser diode. It should be noted that the fixed resistors R1 and R2 for each color may all have the same resistance value.

The printer 10 of this embodiment can also adjust the light emission amount using the PWM signals PWM1 and PWM2 output from the ASIC 72. For example, during factory shipment of printer 10, the light emission amount of beam LB actually irradiated onto photoconductor drum 41 can be adjusted by an operator while observing the beam. The adjustment is performed by modifying the duty ratio of PWM signal PWM1 to achieve the particular light emission amount of laser beam L.

After shipment, printer 10 controls the light emission amount of laser beam L based on the PWM signal PWM1 with the duty ratio adjusted by the operator. First light amount adjustment circuit 101 ensures that the light emission amount remains constant. For instance, increasing the duty ratio of PWM signal PWM1 leads to an increase in input voltage Vin1, which in turn raises reference voltage Vref1. As a result, current Ild1 increases, allowing the light emission amount of first laser diode LD1 to be increased. Conversely, decreasing the duty ratio of PWM signal PWM1 reduces input voltage Vin1, leading to a decrease in reference voltage Vref1. This reduction in reference voltage Vref1 results in a lower light emission amount of first laser diode LD1. The PWM signal PWM2 can be adjusted in the same manner as PWM signal PWM1.

For example, if a variable resistor is connected between the first output terminal 111 and the LD ground GND2, the detection voltage Vpd1 can be adjusted even after the manufacturing of the printer 10 by changing the resistance value of the variable resistor. In other words, the light emission amount of the first laser diode LD1 can be adjusted. However, this approach would require a variable resistor for each light amount adjustment circuit and for each color, leading to an increase in the number of components and manufacturing costs. In contrast, in this embodiment, printer 10 is configured without a variable resistor and instead includes a fixed resistor R1 between first output terminal 111 and the LD ground GND2. The light emission amount of the first laser diode LD1 can be adjusted even after the manufacturing of printer 10 by modifying the PWM signal PWM1.

When adjusting the reference voltage Vref1 using PWM signal PWM1, the input voltage Vin1 must be adjustable within a range that corresponds to an adjustment range of the light emission amount of the first laser diode LD1. In other words, it is necessary to expand the range of voltage values that can be adjusted for the input voltage Vin1. For instance, if the reference voltage Vref1 is adjusted within a range of 1.5 V to 0.3 V, the smaller the reference voltage Vref1, meaning the smaller the input voltage Vin1, the greater the impact of potential deviation caused by GND fluctuation. For example, when adjusting the reference voltage Vref1 to 0.3 V, if a deviation of approximately 30 mV occurs due to GND fluctuation, a deviation of approximately-10% relative to the target value will result.

To address this issue, the generation circuit 81 in this embodiment suppresses GND fluctuation by matching the reference potential for both the on-voltage and off-voltage to the reference potential of the main ground GND1, as described above. As a result, even when the duty ratio of the PWM signal PWM1 is reduced and the input voltage Vin1 is decreased, the influence of GND fluctuation remains minimal. This allows for precise adjustment of the reference voltage Vref1 and, consequently, accurate control of the light emission amount of the first laser diode LD1.

The first embodiment described above provides the following advantages.
(1) The generation circuit 81 of this embodiment generates a particular voltage (e.g., 3.3 V) with reference to the reference potential of the LD ground GND2 and, in accordance with the PWM signal PWM1, alternately switches between an on-voltage based on the particular voltage with reference to the LD ground GND2 and an off-voltage that is the reference potential of the LD ground GND2, outputting it to the first smoothing circuit 115. The first smoothing circuit 115 smooths the on-voltage and off-voltage to generate the reference voltage Vref1 and outputs the reference voltage Vref1 to the LD driver 79.

As a result, the LD board 75 includes the generation circuit 81 (including the first resistor R3A, the second resistor R4A, the first transistor TR1, etc.), which alternately switches and outputs the on-voltage or off-voltage according to the PWM signal PWM1. The generation circuit 81 outputs the input voltage Vin1, in which both the on-voltage and off-voltage are referenced to the reference potential of the LD ground GND2, to the first smoothing circuit 115. Therefore, the reference voltage Vref1 is input to the LD driver 79 without deviation from the reference voltage Vref1 intended by the ASIC 72, allowing the LD driver 79 to properly perform light amount adjustment.
(2) Additionally, the ASIC 72 has an open-collector function that outputs the PWM signal PWM1 from the first output terminal 117 by turning the first switch SW1 on and off. The emitter of the first transistor TR1 is connected to the linear regulator 113CK, the base is connected to the first output terminal 117 via the harness 73, and the collector is connected to the LD ground GND2 via the first resistor R3A. The connection portion 121 between the collector of the first transistor TR1 and the first resistor R3A is connected to the first smoothing circuit 115. Then, the voltage of the connection portion 121, which is referenced to the reference potential of the LD ground GND2, is output as the input voltage Vin1 to the first smoothing circuit 115.

Accordingly, when the ASIC 72 turns on the connection between the main ground GND1 and the first output terminal 117 (as shown in FIG. 6A), current flows from the linear regulator 113CK through the emitter of the first transistor TR1 toward the main ground GND1. The input voltage Vin1 at the connection portion 121, which is referenced to the reference potential of the LD ground GND2, is determined by the 3.3 V DC voltage generated by the linear regulator 113CK and the resistance value of the first resistor R3A. The generation circuit 81 can output the on-voltage to the first smoothing circuit 115.

When the ASIC 72 turns off the connection between the main ground GND1 and the first output terminal 117, no current flows from the linear regulator 113CK through the emitter of the first transistor TR1 toward the main ground GND1. The input voltage Vin1 at the connection portion 121 becomes the off-voltage, which is the reference potential of the LD ground GND2. The generation circuit 81 can output the off-voltage to the first smoothing circuit 115.
(3) Additionally, the second resistor R4A is connected between the collector of the first transistor TR1 and the connection portion 121. The first resistor R3A is connected between the connection portion 121 and the LD ground GND2.

Accordingly, the input voltage Vin1 is a divided voltage of the 3.3 V DC voltage generated by the linear regulator 113CK using the first resistor R3A and the second resistor R4A. The upper limit value of the reference voltage (Vref1) can be determined by the first and second resistors R3A and R4A.
(4) Additionally, the linear regulator 113 converts the 5 V DC voltage Vcc2 input from the DC/DC converter 107 of the main board 71 via the harness 73 to generate a 3.3 V DC voltage.

Accordingly, the linear regulator 113 operates with reference to the reference potential of the LD ground GND2 and converts the 5 V DC voltage input from the DC/DC converter 107 via the harness 73 to generate a 3.3 V DC voltage. Even if the harness 73 becomes longer and a voltage difference occurs between the reference potential of the linear regulator 113 and the reference potential of the main board 71, deviation in the voltage difference between the input and output of the linear regulator 113 from the desired dropout voltage can be suppressed, thereby ensuring stable operation of the transistor within the linear regulator 113. As a result, the output voltage of the linear regulator 113 can be maintained at the target value of 3.3 V.
(5) Additionally, each of the four semiconductor lasers 77 includes a first laser diode LD1 and a second laser diode LD2. The LD board 75 is provided with a first transistor TR1, a first smoothing circuit 115, and a first light amount adjustment circuit 101 corresponding to the first laser diode LD1, as well as a second transistor TR2, a second smoothing circuit 116, and a second light amount adjustment circuit 102 corresponding to the second laser diode LD2.

Accordingly, simultaneous exposure can be performed using the first and second laser diodes LD1 and LD2. Additionally, the reference voltages Vref1 and Vref2, generated by the first and second transistors TR1 and TR2 and the first and second smoothing circuits 115 and 116 corresponding to the first and second laser diodes LD1 and LD2, can suppress deviations from the reference voltage intended by ASIC 72. As a result, the LD driver 79 can appropriately perform light amount adjustment for the first and second laser diodes LD1 and LD2.
(6) Additionally, the first light amount adjustment circuit 101 adjusts the detected voltage Vpd1, which indicates the light emission amount of the first laser diode LD1 of the semiconductor laser 77, so that it becomes the reference voltage Vref1 (an example of the reference value in the present application). The first light amount adjustment circuit 101 is connected to the LD ground GND2 via the fixed resistor R1.

Accordingly, by changing the resistance value of the fixed resistor R1, the value of the detected voltage Vpd1 can be adjusted, allowing the light emission amount of the first laser diode LD1 to be adjusted based on the resistance value of the fixed resistor R1. Furthermore, after the printer 10 has been manufactured, the reference voltage Vref1 can be adjusted by changing the duty ratio of the PWM signal PWM1 output by the ASIC 72. This eliminates the need to modify the resistance value after manufacturing.
(7) Additionally, the semiconductor laser 77, LD driver 79, and photoconductor drum 41 are arranged corresponding to each YMCK color. Among the fixed resistors R1 connected to the first light amount adjustment circuits 101 corresponding to each color, the resistance value of at least one fixed resistor R1 may be set to a different value from the resistance values of the fixed resistors R1 corresponding to the other colors.

Accordingly, by changing the resistance value of the fixed resistor R1 connected to the first light amount adjustment circuit 101 corresponding to each color, the light emission amount of the first laser diode LD1 can be adjusted for each color.
(8) Additionally, the resistance value of the fixed resistor R1 connected to the first light amount adjustment circuit 101, which is arranged corresponding to multiple colors, may be set according to the optical characteristics of the optical path from the semiconductor laser 77 of each YMCK color to the photoconductor drum 41. Accordingly, the resistance value of the fixed resistor R1 for each color can be set based on factors such as the optical path length and the number of lenses. This allows the light emission amount of the first laser diode LD1 to be adjusted according to the optical path length and other factors specific to each color's laser beam L.
(9) Additionally, the LD board 75 is formed as an elongated plate along the second direction (see FIG. 4). The four semiconductor lasers 77Y, 77M, 77C, and 77K are arranged at the central part of the LD board 75 in the second direction. The LD driver 79K is positioned on the opposite side of the LD drivers 79Y, 79M, and 79C in the second direction with respect to the four semiconductor lasers 77. The linear regulator 113CK is positioned on the opposite side of the linear regulator 113YM in the second direction with respect to the four semiconductor lasers 77 and the four LD drivers 79.

This configuration allows the linear regulator 113CK, which corresponds to black and cyan, to be positioned in the longitudinal direction of the LD board 75, with the four semiconductor lasers 77 and the four LD drivers 79 placed in between, and on the opposite side of the linear regulator 113YM, which corresponds to yellow and magenta. As a result, the two linear regulators 113CK and 113YM can be placed at positions separated from the semiconductor lasers 77, with the LD drivers 79 in between. Furthermore, the two heat-generating linear regulators 113CK and 113YM can also be positioned apart from each other. This arrangement reduces the impact of heat generated by the linear regulators 113CK and 113YM on the semiconductor lasers 77, thereby improving the accuracy of image formation.

### Second Embodiment

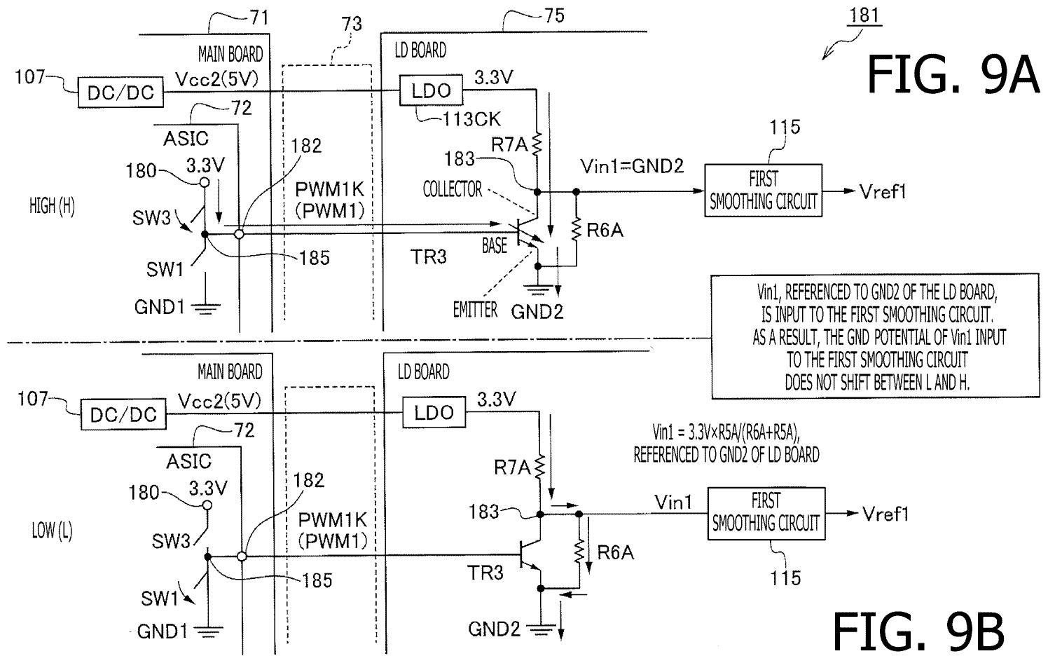

Next, the second embodiment of the present application will be described. In the generation circuit 81 of the first embodiment described above, a circuit employing a PNP transistor as the semiconductor transistor was adopted. In contrast, the generation circuit 181 included in the printer of the second embodiment differs from the generation circuit 81 of the first embodiment in that it employs a circuit with an NPN transistor as the semiconductor transistor. FIGS. 9A and 9B correspond to FIGS. 6A and 6B of the first embodiment and shows a portion of the generation circuit 181 according to the second embodiment. In the following description, components that are the same as those in the first embodiment are denoted by the same reference numerals, and their descriptions are omitted as appropriate.

As shown in FIGS. 9A and 9B, the generation circuit 181 includes a third resistor R6A, a fourth resistor R7A, and a first transistor TR3, in addition to the linear regulator 113CK and the first smoothing circuit 115. One end of the fourth resistor R7A is connected to the output terminal of the linear regulator 113CK, while the other end is connected to a connection portion 183. One end of the third resistor R6A is connected to the connection portion 183, while the other end is connected to the LD ground GND2. The first transistor TR3 is an NPN transistor, with its collector connected to the fourth resistor R7A (connection portion 183). The emitter of the first transistor TR3 is connected to the LD ground GND2. Accordingly, the first transistor TR3 and the third resistor R6A are connected in parallel between the fourth resistor R7A and the LD ground GND2. The collector of the first transistor TR3 serves as an example of an input terminal of the semiconductor transistor, which receives an input of current or voltage. The emitter of the first transistor TR3 serves as an example of an output terminal of the semiconductor transistor, from which current or voltage is output. The base of the first transistor TR3 serves as an example of a control terminal of the semiconductor transistor, which controls the operation of the semiconductor transistor.

ASIC 72 includes a first switch SW1, a third switch SW3, an internal voltage section 180, and a second output terminal 182. The base of the first transistor TR3 is connected to the second output terminal 182 via the harness 73. The internal voltage section 180 serves as a terminal that supplies, for example, a 3.3 V DC voltage and is connected to a connection portion 185 via the third switch SW3. The connection portion 185 is connected to the second output terminal 182. Additionally, the connection portion 185 is connected to the main ground GND1 via the first switch SW1.

The second output terminal 182 is a push-pull output. ASIC 72 switches between the following two connection states:
(a) First connection (shown in FIG. 9B): The third switch SW3 is turned off, disconnecting the internal voltage section 180 from the second output terminal 182, while the first switch SW1 is turned on, connecting the main ground GND1 to the second output terminal 182.
(b) Second connection (shown in FIG. 9A): The third switch SW3 is turned on, connecting the internal voltage section 180 to the second output terminal 182, while the first switch SW1 is turned off, disconnecting the main ground GND1 from the second output terminal 182.

By alternately opening and closing the first switch SW1 and the third switch SW3 at a particular frequency, ASIC 72 switches between the first and second connections. This operation enables ASIC 72 to output the voltage of the pulse-width modulation (PWM) signal PWM1 from the second output terminal 182.

The base of the second transistor TR2 receives the voltage of the PWM signal PWM1 from the second output terminal 182, depending on the on/off state of the first switch SW1 and the third switch SW3.

Additionally, the connection portion 183, where the fourth resistor R7A and the collector of the first transistor TR3 are connected, is connected to the first smoothing circuit 115. The first smoothing circuit 115 receives the voltage of the connection portion 183 as an input voltage Vin1, smooths the voltage, and outputs it as the reference voltage (reference voltage) Vref1 to the first light amount adjustment circuit 101.

When ASIC 72 is in the second connection state shown in FIG. 9A (i.e., when the third switch SW3 is ON and the first switch SW1 is OFF), current flows from the internal voltage section 180 through the second output terminal 182 and the base-emitter path of the first transistor TR3 toward the LD ground GND2. This allows current to flow from the collector to the emitter of the first transistor TR3. As a result, current flows from the linear regulator 113CK through the collector-emitter path of the first transistor TR3 toward the LD ground GND2. No current flows through the third resistor R6A, which is connected in parallel with the first transistor TR3. Since the voltage drop caused by the first transistor TR3 is negligible, the voltage of the connection portion 183 (input voltage Vin1), relative to the LD ground GND2, is essentially the reference potential of the LD ground GND2 itself. The reference potential of the LD ground GND2 itself serves as the OFF voltage. The first smoothing circuit 115 receives this OFF voltage as its input.

On the other hand, when ASIC 72 is in the first connection state shown in FIG. 9B (i.e., when the third switch SW3 is OFF and the first switch SW1 is ON), no current flows from the internal voltage section 180 through the second output terminal 182 and the base-emitter path of the first transistor TR3 toward the LD ground GND2. No current flows from the collector to the emitter of the first transistor TR3, and the first transistor TR3 remains in the OFF state. Current flows from the linear regulator 113CK through the fourth resistor R7A and the third resistor R6A toward the LD ground GND2. The voltage of the connection portion 183 (input voltage Vin1), relative to the reference potential of the LD ground GND2, is the ON voltage obtained by dividing the output voltage of the linear regulator 113CK using the fourth resistor R7A and the third resistor R6A (i.e., 3.3 V×R6A/(R7A+R6A)). The input voltage Vin1 is determined by the voltage generated by the linear regulator 113CK and the resistance values of the fourth resistor R7A and the third resistor R6A. The circuit including the first transistor TR3, the fourth resistor R7A, and the third resistor R6A (switching circuit) alternately switches between the ON voltage (3.3 V×R6A/(R7A+R6A)) referenced to the LD ground GND2 and the OFF voltage, which is the reference potential of the LD ground GND2, and outputs it to the first smoothing circuit 115.

Therefore, even when using the NPN-type first transistor TR3 in the second embodiment, both the ON voltage in the first connection state and the OFF voltage in the second connection state are voltages referenced to the LD ground GND2 (input voltage Vin1). This configuration suppresses the occurrence of GND floating and allows the reference voltage (reference voltage) Vref1 to be output with high accuracy.

Accordingly, the second embodiment achieves the same effects as the first embodiment. In addition, the second embodiment further provides the following effects:
(1) In the second embodiment, ASIC 72 outputs the PWM signal PWM1 from the second output terminal 182 by switching between the first connection and the second connection using the first switch SW1 and the third switch SW3. The first transistor TR3 and the third resistor R6A are connected in parallel between the fourth resistor R7A and the LD ground GND2. The generation circuit 181 outputs the input voltage Vin1 (ON voltage, OFF voltage) at the connection portion 183, referenced to the LD ground GND2, to the first smoothing circuit 115.

Accordingly, in both the ON voltage of the first connection and the OFF voltage of the second connection, the input voltage Vin1 referenced to the LD ground GND2 can be output from the connection portion 183 to the first smoothing circuit 115.
(2) Additionally, the fourth resistor R7A is connected between the linear regulator 113CK and the collector of the first transistor TR3. As a result, the input voltage Vin1 at the connection portion 183, which is output by the generation circuit 181, is a voltage obtained by dividing the 3.3 V DC voltage output from the linear regulator 113CK using the third resistor R6A and the fourth resistor R7A. The upper limit of the reference voltage (reference voltage) Vref1 can be determined by the third resistor R6A and the fourth resistor R7A.

It should be noted that the present invention is not limited to the above-described embodiments, and various modifications can be made without departing from the spirit of the invention. For example, the circuit configuration of each of the above embodiments is merely an example. For instance, the generation circuit 81 of the first embodiment may be configured without including the second resistors R4A and R4B. Additionally, the semiconductor laser (semiconductor laser) 77 has been described as including two light-emitting elements, the first laser diode LD1 and the second laser diode LD2, but it is not limited to this configuration. The semiconductor laser (semiconductor laser) 77 may be configured with only one light-emitting element or with three or more light-emitting elements.

Moreover, a variable resistor may be connected between the first output terminal 111 of the current mirror circuit 105 and the LD ground GND2, or between the second output terminal 112 and the LD ground GND2. This allows the light emission amount of the first and second laser diodes LD1 and LD2 to be adjusted by changing the resistance value of the variable resistor. Furthermore, while the linear regulator 113CK of the generation circuit 81K has been shared with the generation circuit 81C, it may instead be shared with the generation circuits 81Y and 81M for other colors (yellow (Y) and magenta (M)). Additionally, the mounting positions of the components on the LD board 75, as shown in FIG. 4, are merely examples. For instance, the semiconductor laser 77 may be positioned at an end of the LD board 75 in the second direction, while the linear regulators 113CK and 113YM may be positioned at the central part of the LD board 75.

Furthermore, in each of the above-described embodiments, a color laser printer capable of color printing has been adopted as the image forming apparatus of the present application. However, the present invention is not limited to this configuration. The image forming apparatus of the present application may also be a monochrome laser printer. Accordingly, the image forming apparatus of the present application may be configured with only a single set of an LD driver and a semiconductor laser (semiconductor laser).

Moreover, the laser unit of the present application is not limited to devices used for printing; it may also be used in devices such as laser scanners for scanning purposes. Therefore, the image forming apparatus of the present application is not limited to a printer but may also be a scanner or a fax machine. Additionally, the image forming apparatus of the present application may be a multifunction device equipped with multiple functions such as printing, copying, faxing, and scanning. Consequently, the configuration of the laser unit may be appropriately modified according to the functions provided by the image forming apparatus.

What is claimed is:

1. An image forming apparatus, comprising:
a laser unit including a semiconductor laser, a polygon mirror configured to deflect a laser beam emitted from the semiconductor laser, an LD driver configured to control light emission amount of the semiconductor laser based on a reference voltage, and an LD board including an LD reference potential section configured to provide a reference potential for the LD driver, the LD driver being mounted on the LD board;
a photoconductor drum configured to be exposed to the laser beam deflected by the polygon mirror;
a controller including hardware and configured to output a pulse-width modulation signal to indicate the reference potential to the LD driver; and
a main board implemented with the controller, the main board including a main reference potential section configured to provide a reference potential of the controller, the main reference potential section being electrically connected to the LD reference potential section via a harness,
wherein the LD board comprises:
a voltage generation circuit configured to generate a particular voltage with reference to the reference potential of the LD driver;
a switching circuit configured to output an ON-voltage and an OFF-voltage alternately based on the pulse-width modulation signal, the ON-voltage being based on the particular voltage, the OFF-voltage being the reference potential of the LD driver; and
a smoothing circuit configured to generate the reference voltage by smoothing the ON-voltage and the OFF-voltage output by the switching circuit and to output the generated reference voltage to the LD driver.

2. The image forming apparatus according to claim 1,
wherein the controller includes a first output terminal and is configured to output the pulse-width modulation signal by switching a connection between the main reference potential section and the first output terminal on and off,
wherein the switching circuit has a semiconductor transistor and a first resistor, an input terminal of the semiconductor transistor being connected to the voltage generation circuit, a control terminal of the semiconductor transistor being connected to the first output terminal via the harness, an output terminal of the semiconductor transistor being connected to the LD reference potential section via the first resistor, a connection portion between the output terminal of the semiconductor transistor and the first resistor being connected to the smoothing circuit, and
wherein the switching circuit is configured to output a voltage of the connection portion with reference to a reference potential of the LD reference potential section to the smoothing circuit.

3. The image forming apparatus according to claim 1,
wherein the switching circuit has a second resistor,
wherein the second resistor is connected to a portion between the output terminal of the semiconductor transistor and the connection portion, and
wherein the first resistor is connected to a portion between the connection portion and the LD reference potential section.

4. The image forming apparatus according to claim 1,
wherein the controller includes an internal voltage section and a second output terminal,
wherein the controller is configured to output the pulse-width modulation signal from the second output terminal by switching a connection state between first connection and second connection, the first connection being a connection that disconnects the internal voltage section from the second output terminal and connects the main reference potential section to the second output terminal, the second connection being a connection that connects the internal voltage section to the second output terminal and disconnects the main reference potential section from the second output terminal,
wherein the switching circuit includes a third resistor and a semiconductor transistor, one end of the third resistor being connected to the LD reference potential section, the semiconductor transistor being connected in parallel with the third resistor, an output terminal of the semiconductor transistor being connected to the voltage generation circuit, a control terminal of the semiconductor transistor being connected to the second output terminal via the harness, an input terminal of the semiconductor transistor being connected to the LD reference potential section,
wherein a connection portion that the output terminal of the semiconductor transistor and the other end of the third resistor are connected in parallel is connected to the smoothing circuit,
wherein the switching circuit is configured to output a voltage of the connection portion with reference to the reference potential of the LD reference potential section to the smoothing circuit.

5. The image forming apparatus according to claim 4,
wherein the switching circuit includes a fourth resistor, the fourth resistor being connected to a portion between the voltage generation circuit and the output terminal of the semiconductor transistor.

6. The image forming apparatus according to claim 1,
wherein the main board includes a DC/DC converter,
wherein the voltage generation circuit is a low dropout voltage regulator, the voltage generation circuit being configured to generate the particular voltage by converting a DC voltage supplied from the DC/DC converter via the harness.

7. The image forming apparatus according to claim 1,
wherein the semiconductor laser includes two light-emitting elements,
wherein the LD driver includes two light amount adjustment circuits connected to the two light-emitting elements, respectively, the two light amount adjustment circuits being configured to adjust light emission amounts of the two light-emitting elements, respectively,
wherein the switching circuit and the smoothing circuit are provided for each of the two light amount adjustment circuits.

8. The image forming apparatus according to claim 1,
wherein the LD driver includes a light amount adjustment circuit configured to adjust a light emission amount of the light-emitting elements of the semiconductor laser in such a manner that a detection value indicating the light emission amount becomes a reference value,
wherein the light amount adjustment circuit is connected to the LD reference potential section via a fixed resistor.

9. The image forming apparatus according to claim 8,
wherein the semiconductor laser, the LD driver and the photoconductor drum are arranged corresponding to each of multiple colors used for forming an image,
wherein, among the fixed resistors connected to the light amount adjustment circuits included in the LD drivers corresponding to each of the multiple colors, a resistance value of a fixed resistor arranged corresponding to at least one of the multiple colors is different from a resistance value of a fixed resistor corresponding to others of the multiple colors.

10. The image forming apparatus according to claim 9,
wherein a resistance value of a fixed resistor arranged corresponding to each of the multiple colors is set according to optical characteristics of an optical path from the semiconductor laser arranged corresponding to each of the multiple colors to the photoconductor drums arranged corresponding to each of the multiple colors.

11. The image forming apparatus according to claim 10, further comprising:
a first semiconductor laser arranged corresponding to black as the semiconductor laser;
a first LD driver arranged corresponding to black as the LD driver;
a first voltage generation circuit arranged corresponding to black as the voltage generation circuit;
a second semiconductor laser arranged corresponding to a color other than black as the semiconductor laser;
a second LD driver arranged corresponding to a color other than black as the LD driver; and
a second voltage generation circuit arranged corresponding to a color other than black as the voltage generation circuit;
wherein the LD board is formed as an elongated plate along a particular direction,
wherein the first semiconductor laser and the second semiconductor laser are arranged at a central part of the LD board in the particular direction,
wherein the first LD driver is positioned on an opposite side of the second LD driver in the particular direction with respect to the first semiconductor laser and the second semiconductor laser, and
wherein the first voltage generation circuit is positioned on an opposite side of the second voltage generation circuit in the particular direction with respect to the first semiconductor laser, the second semiconductor laser, the first LD driver and the second LD driver.
